(19) United States
(12) Patent Application Publication
(10) Pub. No.: US 2006/0166526 A1
(43) Pub. Date: Jul. 27, 2006

(54) Double printed circuit board with solderless connecting structure

(76) Inventors: Chul-Sub Lee, Daegu (KR); Hang-Gu Cho, Daegu (KR); Yong-Moon Choi, Kyungsangbuk-Do (KR); Chun-Chong Kim, Kyungsangbuk-Do (KR)

Correspondence Address: BARLEY SNYDER, LLC, 1000 WESTLAKES DRIVE, SUITE 275, BERWYN, PA, 19312, US

(21) Appl. No.: 11/336,520

(22) Filed: Jan. 20, 2006

(30) Foreign Application Priority Data
Jan. 21, 2005 (KR) 10-2005-0005850

(51) Int. Cl. H05K 1/00

(52) U.S. Cl. 439/75

(57) ABSTRACT

Disclosed herein is a double printed circuit board with a solderless connecting structure, which electrically connects an upper board and a lower board of the double printed circuit board without soldering. The double printed circuit board comprises upper and lower boards, each having a hole with a conductive layer formed on an inner surface thereof. A pin is press-fitted through the holes of the upper and lower boards, and has upper and lower compliant portions formed at upper and lower portions of a pin body to electrically connect the upper board and the lower board, respectively. Since the pin comprises the upper and lower compliant portions, the pin can maintain stable connection between circuits of the upper and lower boards while being firmly coupled to the printed circuit boards, and minimize environmental contamination due to lead.

### FIELD OF THE INVENTION

The present invention relates to a printed circuit board (PCB), and more particularly to a double printed circuit board with a solderless connecting structure.

### BACKGROUND

Generally, a printed circuit board serves to interconnect various electronic components forming circuits. The PCB comprises a planar board made of a synthetic resin, conductive layers coated on upper and lower surfaces of the planar board to constitute a circuit through which power and signals flow, and holes, so that various components are inserted through the holes, soldered and connected via the circuit. With this construction, the various components are able to perform their desired function.

In addition, in order to place a number of components in a limited space, a technology has been suggested, wherein a plurality of PCBs constructed as described above are stacked, and connected to each other. In order to interconnect circuits of the respective PCBs, as shown in FIG. 4, a pin 500 is inserted through holes 300 of upper and lower boards 100 and 200 having conductive areas 400 formed thereon, and electrically connects, with the aid of a lead based solder 600, the upper and lower boards 100 and 200.

However, as environmental contamination caused by disposal of lead (Pb) waste has become a serious concern, the use of lead in PCB manufacture has been gradually restricted in many countries. Accordingly, it is necessary to provide a solderless printed circuit board which does not use Pb.

### SUMMARY

The present invention has been made to solve the above problems, and it is an object of the present invention, among others to provide a double printed circuit board with a solderless connecting structure, which allows an upper board and a lower board of the double printed circuit board to be electrically connected without soldering.

It is further object of the present invention to allow the easy insertion of a pin through holes of upper and lower boards.

It is another object of the present invention to ensure firm and stable coupling and connection of the pin through the holes of the upper and lower boards.

It is yet another object of the present invention to prevent conductive layers of the holes from being damaged by scratches created due to repetitious contact of upper and lower contact protrusions of the pin with the hole of the upper board occurring when the pin is inserted through the holes of the upper and lower boards, in which the upper and lower contact protrusions are formed on a body of the pin, and correspond to the holes of the upper and lower boards.

It is yet another object of the present invention to prevent undesired contact of the upper contact protrusion with the hole of the upper board occurring when the pin is inserted through the holes of the upper and lower boards by enlarging the hole of the upper boards.

In accordance with an embodiment of the invention, the above and other objects can be accomplished by the provision of a double printed circuit board with a solderless connecting structure. Upper and lower boards, each have a hole with a conductive layer formed on an inner surface thereof. A pin is press-fitted through the holes of the upper and lower boards, and has upper and lower compliant portions formed at upper and lower portions of a pin body to electrically connect the upper board and the lower board to each other.

### BRIEF DESCRIPTION OF THE DRAWINGS

The invention will be more clearly understood from the following detailed description taken in conjunction with the accompanying drawings, in which:

FIG. 1 is an exploded perspective view illustrating a section of a double printed circuit board in accordance with one embodiment of the invention;

FIG. 2 is a transverse cross-sectional view illustrating a coupled state of the double-PCB of FIG. 1;

FIG. 3 is a front view illustrating a pin for the double-PCB in accordance with another embodiment of the present invention; and

FIG. 4 is a longitudinal cross-sectional view illustrating one example of a conventional PCB connecting pin.

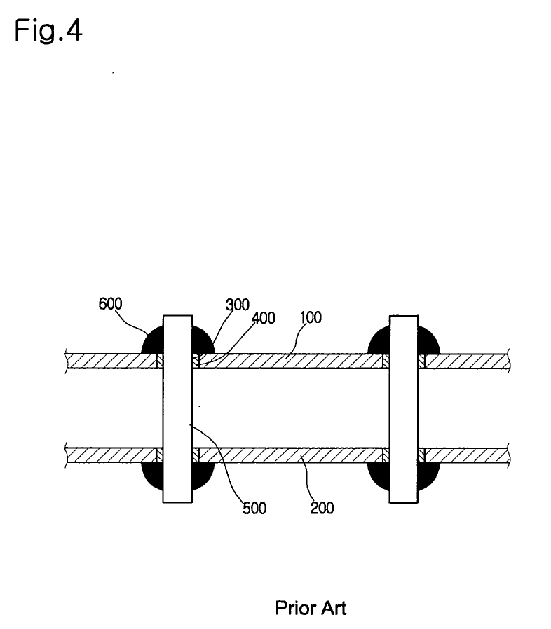

### DESCRIPTION OF THE EMBODIMENTS

Embodiments of the present invention will be described in detail with reference to the accompanying drawings, in which like components are denoted by the same reference numerals, and repetitious descriptions thereof will be omitted.

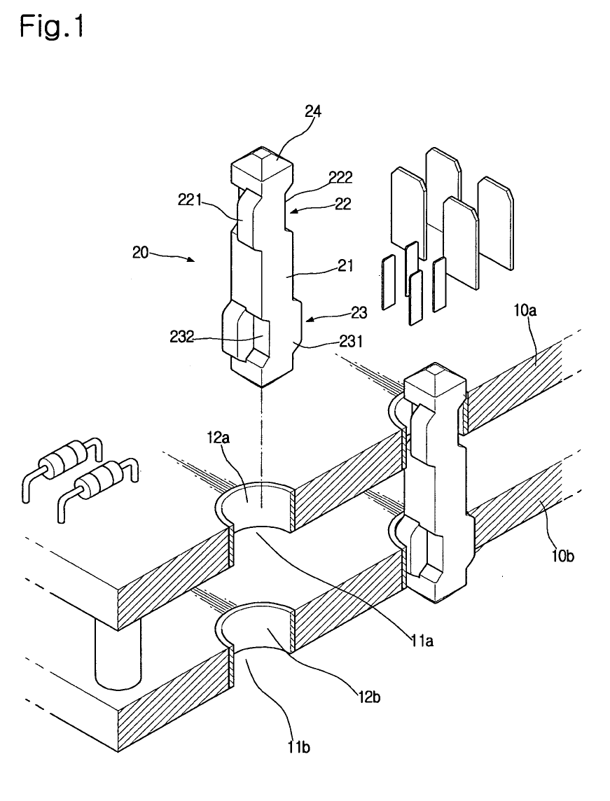

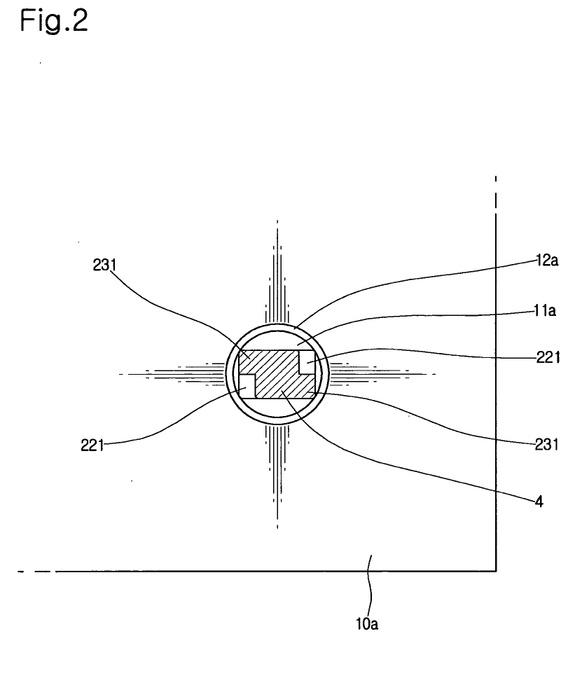

FIG. 1 is an exploded perspective view illustrating a double printed circuit board in accordance with one embodiment of the present invention, and FIG. 2 is a transverse cross-sectional view illustrating a coupled state of the double-PCB of FIG. 1. As shown in the drawings, the double printed circuit board of the invention comprises upper and lower boards 10a and 10b having holes 11a and 11b with a conductive layer 12a, 12b formed on an inner surface thereof, respectively, and a pin 20 which is press-fitted through the holes 11a and 11b of the upper and lower boards, and has upper and lower compliant portions 22 and 23 formed at upper and lower portions of a pin body 21 to electrically connect the upper board and the lower board 10a and 10b, thereby allowing the upper and lower boards 10a and 10b to be stably connected without soldering.

Each of the upper and lower boards 10a and 10b has basic circuits formed thereon to operate various electric/electronic components. Each of the upper and lower boards 10a and 10b comprises a planar board made of a synthetic resin, conductive traces (not shown) attached to upper and lower surface thereof to constitute a circuit through which current or electric signals flow, and a plurality of holes 11a, 11b such that the various components are inserted through the holes 11a, 11b, and connected via the circuit and soldering. With this construction, the various components are firmly secured to the upper and lower boards 10a, 10b, thereby performing their desired function.

The holes 11a and 11b are formed through the upper and lower boards 10a and 10b, and face each other to allow the circuits of the respective boards 10a and 10b to be connected with each other when the upper and lower boards 10a and 10b are fixed as double layers in a separated state. The holes 11a and 11b have metal conductive layers 12a and 12b formed on an inner surface thereof to connect with the circuits of the boards, so that the upper and lower boards 10a and 10b are electrically connected with each other through contact with the pin 20 as described below.

As described above, the pin 20 serves to connect two printed circuit boards, such as upper and lower boards 10a and 10b, with each other in a vertically stacked state. The pin body 21 of the pin 20 is conductive, and has a rod shape. The upper and lower compliant portions 22 and 23 are formed, and separated from each other on an outer surface of the pin body 21 such that, when the pin 20 is inserted through the holes 11a and 11b, the upper and lower compliant portions 22 and 23 are resiliently supported on the inner surfaces of the holes 11a and 11b, and contact the conductive layers 12a and 12b, thereby allowing the upper and lower boards 10a and 10b to be electrically connected therethrough.

The upper and lower compliant portions 22 and 23 include pairs of contact protrusions 221 and 231 formed outwardly on the pin body 21, respectively, such that the contact protrusions 221 and 231 contact the conductive layers 12a and 12b to electrically connect the pin 20 with the upper and lower boards 10a and 10b. The pairs of contact protrusions 221 and 231 are integrally formed to the upper and lower portions of the pin body 21 by pressing or other processes, so that electric resistance is minimized in the pin 20.

Each pair of contact protrusions 221 or 231 extends from opposite sides of the upper or lower compliant portion 22 or 23 such that the contact protrusions 221 or 231 are alternately formed on the opposite sides, respectively. As a result, double contacts are created between each pair of contact protrusions 221 or 231 and an associated conductive layer 12a or 12b, thereby minimizing resistance, and allowing a good connection between the pin 20 and the upper and lower boards 10a and 10b irrespective of damage to the conductive layers 12a and 12b.

In addition, the contact protrusions 221 and 231 are alternately formed on the upper and lower compliant portions 22 and 23 with respect to the longitudinal axis of the pin body 21. Accordingly, if the conductive layer 12a of the upper board 10a is damaged when the lower compliant portion 23 is fixed to the hole 11b of the lower board 10b through the hole 11a of the upper board 10a, the contact protrusions 221 of the upper compliant portion 22 are brought into contact with different positions of the conductive layer 12a from positions through which the protrusions 231 of the lower compliant portion 23 pass, thereby maintaining positive connection between the pin and the boards.

The upper and lower compliant portions 22 and 23 of this embodiment further include pairs of recesses 222 and 232 corresponding to the pairs of contact protrusions 221 and 231 on the pin body 21, respectively, such that each recess is formed on an opposite side of the pin body 21 to each contact protrusion 221 and 231. As a result, a clearance for receiving resilient deformation of the contact protrusions 221 and 223 is increased, allowing the contact protrusions 221 and 223 to be brought into firm contact with the inner surface of the holes 11a and 11b.

In addition, the pin body 21 of this embodiment has insert portions 24 formed at upper and lower ends thereof, and oppositely slanted with respect to a central axis of the pin body 21 to form a conical-shape or a polygonal cone shape. Accordingly, when the pin 20 is inserted through the holes 11a and 11b, both ends of the pin 20 do not interfere with the holes 11a and 11b, thereby removing difficulties for the connection of the printed circuit boards 10a and 10b.

In the construction described above, at an initial stage of inserting the pin body 21 to the hole 11a of the upper board 10a via the insert portion 24 with the upper and lower boards 10a and 10b overlapping each other, the contact protrusions 231 of the lower compliant portion 23 formed at the lower portion of the pin body 21 pass through the holes 11a of the upper board 10a along with friction on the inner surface of the hole 11a. Then, when continuously pushing the pin body 21, the lower compliant portion 23 is inserted through the hole 11b of the lower board 10b, and brought into contact with the conductive layer 12b on the inner surface of the lower substrate 10b so that the pin 20 is fixed to the upper and lower boards 10a and 10b and electrically connects them.

In addition, when the upper compliant portion 22 is inserted through the hole 11a of the upper board 10a with the lower compliant portion 23 fixed to the hole 11b of the lower board 10b, the contact protrusions 221 of the upper compliant portion 22 are brought into tight contact with the conductive layer 12a on the inner surface of the hole 11a of the upper board 10a. As a result, the upper and lower compliant portions 22 and 23 are fixed to the upper and lower boards 10a and 10b, respectively, and the circuits of the upper and lower boards 10a and 10b are electrically connected when current flows through the pin body 21.

Furthermore, a support can be inserted to a space defined between the upper and lower boards 10a and 10b such that the upper and lower boards 10a and 10b are spaced a predetermined distance from each other while being firmly fixed thereby. As a result, the upper and lower boards 10a and 10b can be firmly fixed to each other via the support.

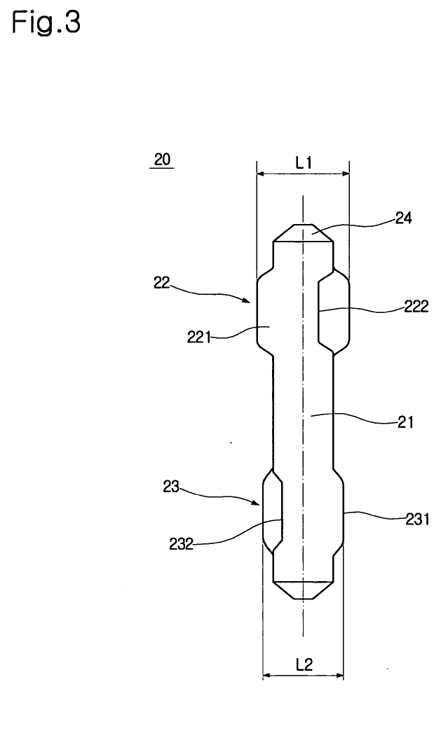

FIG. 3 is a front view illustrating a major part of a pin for the double-PCB in accordance with another embodiment of the invention. A pin 20 of this embodiment has the same construction as that of the above embodiment except that a width L1 of an upper compliant portion 22 is slightly greater than a width L2 of a lower compliant portion 23.

Accordingly, when contact protrusions 231 of the lower compliant portion 23 is fixed to a hole 11b of a lower board 10b through a hole 11a of an upper board 10a, contact protrusions 221 of the upper compliant portion 22 is firmly fixed inside the hole 11a of the upper compliant portion 22 without enlarging a diameter of the hole 11a or damaging a plated layer 12a of the upper compliant portion 22.

As apparent from the above description, the present invention provides a pin 20 for connecting the printed circuit boards 10a and 10b, which allows two printed circuit boards 10a and 10b disposed in parallel to be firmly connected, and maintains suitable electrical connection therebetween without soldering. Since the pin 20 comprises the upper and lower compliant portions, the pin 20 can maintain a stable connection between the circuits of the circuit boards 10a and 10b while being firmly coupled to the printed circuit boards 10a and 10b, and minimize the environmental contamination due to lead.

In addition, according to the invention, since the pin 20 is formed with the insert portions 24 at either ends thereof, the pin 20 can be smoothly inserted to the printed circuit boards 10a and 10b, which makes insertion of the pin 20 to the holes 11a and 11b of the boards 10a and 10b further convenient with the printed circuit boards 10a and 10b overlapping each other.

In addition, according to the invention, for easy and secure connection between the circuits of the PCBs 10a and 10b when connecting the PCBs 10a and 10b using the pin 20, the pin 20 is formed with the upper and lower compliant portions 22 and 23, which comprise the pairs of contact protrusions 221, 222, 231, 232 outwardly formed on the pin body 21, so that the pin 20 for connection of the PCBs can be easily manufactured.

In addition, according to the invention, each of the upper and lower compliant portions 22 and 23 supports both sides of the inner surface of the hole 11a, 11b by means of the pairs of contact protrusions 221, 222, 231, 232 alternately formed on opposite sides of a pin body 21, so that the compliant portions 22 and 23 can be further securely attached to the conductive layer 12a, 12b, and enhance the connection between the PCBs 10a and 10b.

Furthermore, according to the invention, the upper and lower compliant portions 22 and 23 have the contact protrusions 221, 222, 231, 232 alternately formed with respect to the central axis of the pin body 21, and the upper compliant portion 22 is wider than the lower compliant portion 23, so that electrical connection between the PCBs 10a and 10b can be securely maintained irrespective of damage of the conductive layer 12a due to the friction between the contact protrusions 231 and 232 and the conductive layer 12 a occurring when the pin 20 is inserted through the holes 11a of the upper and lower PCBs 10a and 10b. As a result, it is possible to prevent disconnection between any of the compliant portions 22 and 23 and the PCBs 10a and 10b due to damage of the conductive layer 12a and 12b. Furthermore, even if the contact protrusions 231, 232 of the lower compliant portion 23 enlarge the diameter of the hole 11a of the upper PCB 10a or damages the conductive layer 12a of the hole 11a while passing through the hole 11a of the upper PCB 10a, the upper compliant portion 22 can be firmly fixed inside the hole 11a, thereby maintaining firm connection between the pin 20 and the PCBs 10a and 10b.

It should be understood that the embodiments and the accompanying drawings have been described for illustrative purposes and the present invention is limited by the following claims. Further, those skilled in the art will appreciate that various modifications, additions and substitutions are allowed without departing from the scope and spirit of the invention as set forth in the accompanying claims.

What is claimed is:

1. A double printed circuit board with a solderless connecting structure, comprising:
upper and lower boards, each having a hole with a conductive layer formed on an inner surface thereof; and
a pin press-fitted through the holes of the upper and lower boards, and comprising upper and lower compliant portions formed at upper and lower portions of a pin body to electrically connect the upper board and the lower board, respectively.

2. The double printed circuit board of claim 1, wherein the pin body has insert portions formed at upper and lower ends, and being oppositely slanted with respect to a central axis of the pin body in an inserting direction.

3. The double printed circuit board of claim 1, wherein the upper and lower compliant portions have respective pairs of contact protrusions formed outwardly on the pin body.

4. The double printed circuit board of claim 3, wherein the contact protrusions each extend from opposite sides of the pin body such that the respective contact protrusions are alternately formed on the opposite sides thereof.

5. The double printed circuit board of claim 4, wherein the contact protrusions of the upper and lower compliant portions are each formed on opposing sides of a central axis of the pin body.

6. The double printed circuit board of claim 5, wherein the upper compliant portion is slightly wider than the lower compliant portion.
